(19) United States
(12) Patent Application Publication
(10) Pub. No.: US 2008/0258742 A1
(43) Pub. Date: Oct. 23, 2008

(54) Conductivity measurement device, its manufacture and use

(76) Inventors: Aristotelis Dimitrakopoulos, Saint Martin de Nigelles (FR); Pascal Rajagopalan, Aulnay-Sous-Bois (FR); Celine Le Ninivin, Verneuil sur Seine (FR); Yves Gaignet, Montigny Le Bretonneux (FR); Chester L. Bejtlich, Reading, MA (US)

Correspondence Address: Nields & Lemack, 176 E. Main Street, Suite #5, Westboro, MA, 01581, US

(21) Appl. No.: 11/998,003

(22) Filed: Nov. 28, 2007

(30) Foreign Application Priority Data
Dec. 1, 2006 (FR) 0655276

(51) Int. Cl. G01R 27/02; H01B 13/34

(52) U.S. Cl. 324/693; 216/13

(57) ABSTRACT

The invention relates to a method of manufacturing a device for measuring conductivity of a liquid, in particular ultrapure water, of the kind comprising two conductivity measurement electrodes suitable for defining a cell constant enabling the measurement of the conductivity of the ultrapure liquid, characterized in that it consists of producing each of the electrodes by forming an electrode pattern from electrically conductive material on a substrate of insulating material.

It also relates to the conductivity measuring device obtained by that method and to a device for measuring the Total Organic Carbon quantity implementing that conductivity measuring device.

The present invention concerns the manufacturing of devices for measuring the conductivity of an ultrapure liquid, such as ultrapure water, in particular for devices for measuring organic substances or Total Organic Carbon (TOC) in a sample of liquid.

Numerous modern technological applications require ultrapure water for their operation, in particular in the chemical, pharmaceutical, medical and electronic industries.

Currently, as is described for example in the patent U.S. Pat. No. 4,767,995, the conductivity measurement cells used for example in water purification systems, are composed of at least two parts of electrode-forming conductive material mounted head to foot on the same element body of insulating material with axial overlap. At least one of the electrodes is hollow so as to receive within its hollow the other electrode coaxially with the first part. The space between the two electrodes defines a sample volume on which the measurement is performed.

Such an arrangement is adapted to enable a sufficiently low cell constant to be obtained to enable the measurement of the conductivity of an ultrapure liquid.

It is to be recalled, in this respect, that conductivity is the measurement of the flow of electrons which pass through a substance. It is directly proportional to the concentration of ions, to the charge carried by each of those ions (valency) and to their mobility. This mobility depends on the temperature, and consequently, the measurement of the conductivity also depends on the temperature.

In theoretically pure water, the only two ionic species present arise from the dissociation of water molecules into H⁺ and OH⁻.

Thus, at 25°, the theoretical conductivity of a water sample free from ionic contaminant is equal to 0.055 μS/cm, i.e. a resistivity (inverse of the conductivity) of 18.2 MΩ.cm.

This conductivity is measured by applying an electric potential between the two electrodes immersed in the water sample. It is determined from the voltage and the strength of the current produced within the conductivity measurement cell.

This conductivity measurement is affected by the geometry of the cell, the total surface area of the electrode (s) and the distance separating them (L).

These last two parameters define the cell constant: cell constant=L/s.

In practice, the greater the surface area of the electrode, the higher the strength of the current generated for a given voltage and thus the more precise the current measurement. This means that the lower the cell constant, the more precise the measurement.

This is particularly important in the case of ultrapure water. This is because low cell constants (<0.2 cm⁻¹ in practice) are necessary to obtain a high signal that will be less subject to interference.

One of the favored applications for this type of conductivity measurement cell is the measurement of the Total Organic Carbon (TOC), as described for example in the patent application EP 0 498 888 or the patent U.S. Pat. No. 6,741,084. In practice, a sample of theoretically ultrapure water is subjected to photo-oxidation by means of ultraviolet rays (UV) of which the wavelength is approximately 185 nm, which makes it possible to measure the quantity of organic carbon in the water on the basis of the drop in resistivity resulting from the oxidation by ultraviolet of the organic substances present in the sample of water subjected to the measurement.

Currently, in the mass production method, the elements constituting those cells are generally assembled by hand, which results in particular in variations in the geometry of the cells with respect to the specifications or from one item thereof to another, such as a variation in the relative position of the two electrodes. In practice, this results in variations in the cell constant which affect the precision of the conductivity measurement.

In general terms, the present invention is directed to arrangements making it possible to manufacture devices for measuring conductivity of an ultrapure liquid with very high precision and furthermore leading to other advantages.

It provides, more particularly, a method of manufacturing a device for measuring conductivity of a liquid, in particular ultrapure water, of the kind comprising two conductivity measurement electrodes suitable for defining a cell constant enabling the measurement of the conductivity of an ultrapure liquid, characterized in that it consists of producing each of the electrodes by forming an electrode pattern from electrically conductive material on a substrate of insulating material.

Thus, the present invention not only makes it possible to ensure manufacture with very high precision, in particular from the point of view of the thickness of the electrodes, and thus minimum tolerances, but also to eliminate the manual assembly of cell components during their manufacture by using an automated manufacturing technique, in particular considerably increasing the reproducibility of the cell constant from one cell to another.

This type of manufacturing technology has been proposed for manufacturing sensors for different applications to those for the measurement of the conductivity of an ultrapure liquid (see for example the patent applications US 2005/0247114 and US 2003/0153094), but the person skilled in the art has not until now perceived of the desirability of this kind of technology in the production of devices for measuring conductivity of ultrapure liquids, that is to say devices in which the electrodes must be suitable for obtaining a cell constant enabling the measurement of such a conductivity, and thus, in which that cell constant is a critical parameter.

In practice, conductivity measurement cells in accordance with the invention are manufactured using manufacturing technologies arising from electronics, such as microlithography or screen printing. They are advantageously manufactured by photoetching of electrode patterns on a given substrate material, such as a polymer, for example Mylar® (polyester), or a ceramic, such as quartz glass, it also being possible for the electrode-forming material which is deposited to vary. This is preferably carbon, boron-doped diamond, platinum, silver, gold or titanium.

A temperature sensor, in practice taking the form of a thermistor, is advantageously provided to be placed either upstream or downstream of the conductivity measurement cell or, better still, positioned under one of the electrodes with, possibly, a fine glass interface between the temperature sensor and the space receiving the sample to measure.

This is because one of the major problems in the field of conductivity measurement is that this is greatly affected by variations in temperature. More particularly, the higher the temperature of a sample, the lower the resistivity (due to the mobility of the ions). Thus, to ensure a precise measurement, it is necessary to temperature-compensate the conductivity measurement. To that end, conductivity measurement cells are generally equipped with sample temperature sensors.

Preferably, the temperature sensor is formed using the same manufacturing techniques as those mentioned above for manufacturing the electrodes. Its pattern may thus be formed on the substrate, which makes it possible to precisely position the sensor with respect to the conductivity measurement electrodes and to avoid the damage which may result from the assembly methods of the state of the art. It may be made from polysilicon or boron-doped diamond, for example. In both cases, the substrate is then chosen of quartz glass due to the high temperatures which are required for the deposit. By virtue of these arrangements, it is possible to produce an integrated sensor making it possible to determine the temperature of the sample of the liquid analyzed at the same time as its conductivity, thus eliminating the measurement errors of the conductivity due to the temperature measurement errors.

Furthermore, by virtue of the present invention, a cell window placed on the substrate can be manufactured with the same precision as the substrate, and consequently the sample volume will be reproducible and much smaller than the sample volume necessary with the current technical solutions. This leads to a shorter conductivity measurement time (direct measurement) for the ultrapure water or for any other ultrapure liquid to measure.

The two parts may be assembled using a seal. However, by virtue of the present invention, the two parts, i.e. the substrate and the cell window, may be manufactured with planar surfaces and only a small amount of pressure is then sufficient to retain the two parts against each other in order to maintain fluid-tightness. Thus, there will be no need to bond the two parts together, nor to use a fluid-tight seal.

The absence of adhesive makes it possible in particular to eliminate the organic contaminants coming therefrom and leading to errors in measurement in the case of measuring TOC.

Moreover, in the case of this favored application, the present invention makes it possible to optimize the TOC measurement chamber in terms of volume and thickness of the liquid layer in order for them to be sufficiently small to ensure effective photo-oxidation by UV. Furthermore, the arrangement according to the invention advantageously lends itself to a further development in which the photo-oxidation process is improved, by using a catalytic layer.

The arrangement according to the invention also lends itself to another development combined with the preceding one.

Currently, the TOC measurement devices use a mercury vapor UV lamp operating at two wavelengths, 185 nm and 254 nm. Such a lamp has a certain number of drawbacks: high cost, interference with the signals, increase in the temperature, limited life, lack of reproducibility, loss in effectiveness, etc.

According to the development, a UV lamp emitting a wavelength greater than or equal to 360 nm and less than or equal to 400 nm, and preferably equal to 365 nm, is used in association with a photocatalyst based on a semiconductor material with a wide energy band, preferably based on titanium oxide according to the teachings described in the following documents:

1-Advanced Photochemical Processes, EPA/625/R-98/004, December 1998

2-Photocatalytic oxidation of Gas-Phase BTEX-contaminated Waste Streams, NREL/TP-473-7575, March 1995

3-Photocatalytic thin film cascade for treatment of organic compounds in wastewater, A. H. C. Cha, J. P. Barford, C. K. Cha, Water Science and Technology, vol. 44, 5, 187-195

Titanium dioxide, more particularly in its anatase form, is the preferred catalyst, since it is the most effective in photo-catalytic reactions.

However, other semiconductors such as ZnO, Fe₂O₃, CdS, ZnS, SrTiO₃, CaTiO₃, KTaO₃, Ta₂O₅, and ZrO₂ may be use (M. R. Hoffmann, S. T. Martin, W. Choi., D. W. Bahnemann, Chem. Rev. 95, 69, 1995; A. Fujishima, T. N. Rao, D. A. Tryk, J. Photochem. Photobiol. C: Photochemistry., 1, 1, 2000).

It may also be envisaged to produce mixtures of different forms of photo-catalyst, for example the rutile and anatase forms for titanium dioxide. Furthermore, M. Penpolchaoren, R. Amal, M. Brungs, Journal of Nanoparticle Research, 3, 289, 2001 describe the photo-degradation of saccharose and nitrates by virtue of titanium dioxide particles covered with nano-hematites (TiO₂/Fe₂O₃).

To improve the kinetics of the reaction, transition metals or doping ions are preferably introduced, such as iron, silver or platinum on particles of titanium oxide. The efficiency of TiO₂ suspension modified by the silver ion has thus been studied in the context of the mineralization of saccharose (V. Vamathevan, R. Amal, D. Beydoun, G. Low, S. McEvoy, J. Photochem. Photobiol. A: Chemistry., 148, 233, 2002). The authors have shown the improvement in the reduction of the oxygen by virtue of a better electrons-holes separation with Ag/TiO₂ modified particles compared with particles of pure TiO₂. Thus it has been possible to improve the mineralization speed of certain selective organic compounds (H. Tran, K. Chiang, J. Scott, R. Amal, Photochem. Photobiol. Sci., 4, 565, 2005). It will also be noted that the photo-decomposition of phenol has been studied with a photocatalyst based on TiO₂/SiO₂, which may also be implemented in the context of the present invention.

In practice, as regards for example titanium dioxide, this may be implemented in the form of particles, a deposit on the electrodes (in whole or in part) and/or the substrate, but also in the form of a film of titanium dioxide which may cover the interior portion of the container in contact with the sample.

Also in practice, the wide energy band of the semiconductor material of the photocatalyst has a value less than or equal to that of the titanium dioxide, i.e. of the order of 3.2 eV.

As a variant, the UV lamp is replaced by a xenon flash type UV lamp emitting a wavelength in the spectrum ranging from UV at 160 nm to the visible spectrum at 400 nm.

Such a lamp, which may also be used in association with a photocatalyst of the aforementioned type, has the particular characteristic of providing intense power pulses of short duration.

Thus, according to one embodiment, a small volume for the sample of ultrapure liquid (less than 300 μl in practice) is provided in a conductivity measurement cell manufactured with the techniques arising from microelectronics and comprising an integrated temperature sensor, titanium oxide deposited on the substrate as a photocatalyst and a UV lamp taking the form of a light-emitting diode of which the wavelength is 365 nm.

The photocatalyst may totally or partially cover one or each conductivity measurement electrode pattern or else not be in contact with such a pattern.

Other electronic components relative to the measurement device, such as an analog to digital converter, microcontrollers, a power supply for the UV light emitting diode lamp, etc. are furthermore advantageously integrated into the device, by printing them for example on the back of the substrate, so as to miniaturize the entire device. Thus, a miniature TOC analyzer may be produced capable of being connected to an item of equipment as a complete sub-assembly.

Advantageously, an optical sensor is arranged on the same side as the back of the substrate to detect the signal of the UV light emitting diode for the purpose of quantifying and adjusting the real quantity of energy passing through the ultrapure liquid sample present in the TOC analyzer. Such an arrangement enables real-time detection of the completion of the photo-oxidation step on the basis of the intensity of the signal and also makes it possible to detect possible irregularities within the conductivity measurement cell, such as air bubbles or particles liable to absorb and/or deviate the signal.

The completion of the photo-oxidation step may thus be detected in a simpler and more certain manner than by the methods currently used, i.e., either the determination of the slope of the first and/or second derivative of the curve of conductivity against time, or stopping the photo-oxidation at a given time.

The measurements thus made may also be used to differentiate and quantify the different types of organic material present in the ultrapure liquid sample analyzed, the case arising using a filter to quantify the full spectrum or a specific wavelength (for example 365 nm).

More generally, according to preferred arrangements, which may possibly be combined:

the electrode patterns are formed by etching a layer of material deposited beforehand on the substrate or on an underlying layer itself deposited on that substrate,

the electrically insulating material of the substrate is chosen from the group comprising quartz glass, Mylar® and silicon,

the conductivity measurement electrode-forming electrically conductive material is chosen from the group comprising carbon, platinum, silver, gold, titanium and boron-doped diamond,

conductivity measurement electrode patterns are produced taking the form of two interleaved combs forming an interdigitated structure,

the method further consists of producing a thermistor on the substrate by forming a pattern thereon with semiconductor or conductor material,

the material of the thermistor is chosen from the group comprising polysilicon, platinum and boron-doped diamond,

the or each conductivity measurement electrode-forming pattern, when produced on the underlying layer of thermistor-forming material, is separated therefrom by a deposit of electrically insulating material, preferably silicon dioxide SiO₂ or silicon nitride Si₃N₄.

The invention also concerns a device for measuring conductivity of an ultrapure liquid capable of being manufactured according to the method defined above as well as a TOC measuring device using that conductivity measuring device.

According to preferred arrangements relative to that measuring device, which may possibly be combined:

the device comprises a cell having a conductivity measurement chamber communicating with the outside of the cell by a liquid inlet and outlet provided in the cell, and at least partially covering the patterns of the conductivity measurement electrodes,

the cell comprises two complementary members, one comprising a recess forming the conductivity measurement chamber and the other forming the substrate, the liquid inlet and outlet of the cell being formed in the substrate-forming member,

the device comprises a casing in two parts by virtue of which the cell is housed and means for assembly by clamping the two parts suitable for ensuring the fluid-tightness of the conductivity measurement cell,

the electrically insulating material of the substrate is chosen from the group comprising quartz glass, Mylar® and silicon,

the conductivity measurement electrode-forming electrically conductive material is chosen from the group comprising carbon, platinum, silver, gold, titanium and boron-doped diamond,

the conductivity measurement electrode patterns take the form of two interleaved combs forming an interdigitated structure,

the device further consists of producing a thermistor on the substrate by forming a pattern thereon with conductor or semiconductor material,

the material of the thermistor is chosen from the group comprising polysilicon, platinum and boron-doped diamond,

the or each conductivity measurement electrode-forming pattern, when produced on the underlying layer of thermistor-forming material, is separated therefrom by a deposit of electrically insulating material, preferably silicon dioxide SiO₂ or silicon nitride Si₃N₄,

the device comprises electronic components specific to the device, on the rear face of the substrate.

The device for measuring Total Organic Carbon of a sample of liquid, comprises a device for measuring conductivity as defined above, which has at least one window transparent to ultraviolet rays to perform photo-oxidation of the sample of liquid located in the measurement chamber.

According to preferred arrangements relative to that TOC measuring device, which may possibly be combined:

the device comprises, for the photo-oxidation, UV lamp emitting a wavelength greater than or equal to 360 nm and less than or equal to 400 nm, and preferably equal to 365 nm, and a photo-catalyst deposit based on semiconductor material with a wide energy band on the substrate,

the device comprises, for the photo-oxidation, a xenon flash lamp emitting ultraviolet rays of a wavelength greater than or equal to 160 nm and less than or equal to 400 nm, and, possibly, a photo-catalyst deposit based on semiconductor material with a wide energy band on the substrate,

the wide energy band semiconductor material comprises at least one of a single oxide of a transition metal, a mixed oxide of a transition metal and of an alkali or alkaline-earth metal and of a transition metal sulfide, preferably doped,

the semiconductor material is chosen from the group comprising TiO₂, ZnO, Fe₂O₃, ZrO₂, Ta₂O₅, SrTiO₃, CaTiO₃, KTaO₃, CdS and ZnS,

it comprises an optical sensor arranged at the rear face of the substrate to detect the ultraviolet rays emitted by the ultraviolet lamp,

the ultraviolet lamp is in the form of a light-emitting diode.

Other advantages of the present invention will appear from the reading of the following description, made with respect to the drawings in which:

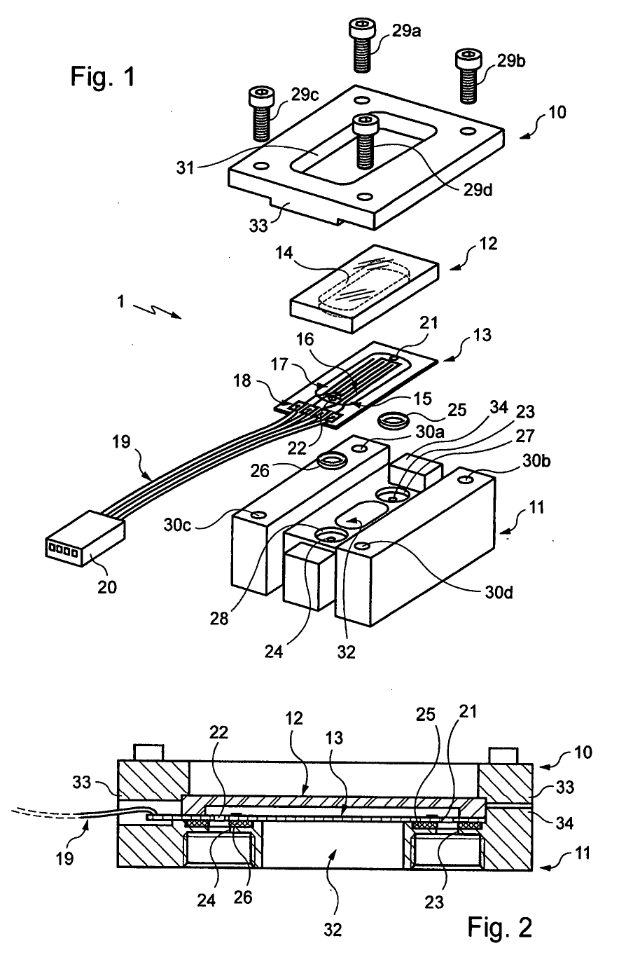

FIG. 1 is an exploded perspective view of a device for measuring conductivity of an ultrapure liquid, in accordance with a preferred embodiment of the present invention;

FIG. 2 is a longitudinal median cross-section, at a larger scale, of the device of FIG. 1;

FIG. 3 is a very diagrammatic plan view, representing the patterns for the conductivity measurement electrodes and the thermistor-forming pattern of the measuring device of FIGS. 1 and 2; and

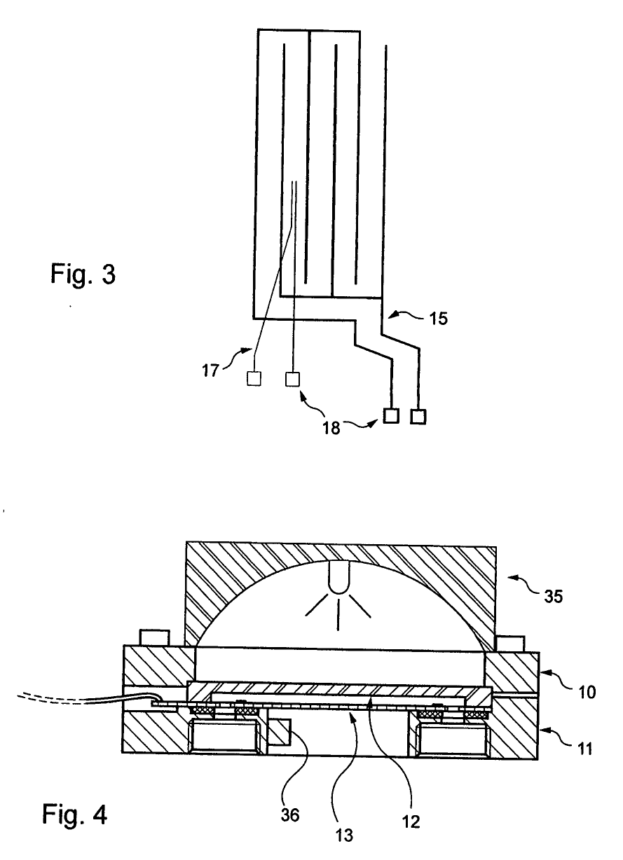

FIG. 4 is a longitudinal median cross-section view of a TOC measuring device.

It should be noted in this connection that the description which follows is that of a preferred embodiment, given by way of non-limiting example.

The device 1 for measuring conductivity of an ultrapure liquid, here ultrapure water, comprises a casing 10 in two parts, 10, 11 of plastics material, here machined, by virtue of which there are housed a window 12 transparent to UV, here of quartz glass, and a substrate 13, also of quartz glass and having several motifs. This window 12 is provided with a recess 14 forming a conductivity measurement chamber adapted to receive the liquid sample to analyze.

With the substrate 13 it forms the actual conductivity measurement cell.

The substrate 13 comprises, to that end, two deposits of electrically conductive material forming patterns of electrodes 15, 16 for conductivity measurement and another deposit of semiconductor material forming a thermistor 17 which serves to determine the temperature of the liquid sample present in the chamber 14. These deposits are made on the face of the substrate 13 that faces the conductivity measurement chamber 14 and they terminate with soldering surfaces 18 situated at one of the ends of the substrate 13, for the connection of electrical connection wires 19 of an electrical connector 20 making it possible to electrically connect the conductivity measurement cell 12, 13 to one or more exterior circuits for determining the temperature and the temperature-compensated conductivity of the sample of ultrapure water present in the chamber 14. The electrode patterns 15, 16 are of course made so as to obtain a low cell constant, in practice less than 0.2 cm⁻¹, enabling the measurement of the conductivity of ultrapure water. In fact, the strips of electrically conductive material forming electrodes are of such dimensions and arrangement as to obtain that cell constant. Furthermore, the substrate 13 comprises two water supply holes 21, 22 which respectively correspond to two holes 23, 24 made in the lower part 11 of the casing, for the purpose of allowing the inlet and outlet of the water analyzed in the chamber 14, in a direction orthogonal to that of the circulation of water therein. Two ‘O’ ring seals 25, 26 each received in a hollow 27, 28 formed in the bottom of the lower part 11 serve to provide fluid-tightness with the substrate 13 posed on top. On the other hand, there is no seal between the substrate 13 and the window 14, fluid-tightness being achieved solely by the clamping of the upper part 10 of the casing onto the lower part 11 using four screws 29a-29d cooperating with internal screw threads 30a-30d formed in the lower part 11 of the casing.

It will moreover be noted that the upper part 10 of the casing is provided with a central opening 31 enabling optical access to the chamber 14, while the lower part 11 has a cavity 32 opening between the two holes 23, 24 formed in the lower part 11 of the casing and arranged so as to be situated under the conductivity measurement chamber 14 and, thereby, the opening 31 formed in the upper part 10 of the casing.

It will also be noted that those lower 11 and upper 10 parts are machined so as to form projections 33, 34 suitable for holding the conductivity measurement cell 12, 13 in place between the lower 11 and upper 10 parts, once the screws 29a-29d have been tightened.

As can be best seen in FIG. 3, the two conductivity measurement electrodes 15, 16 take the form of an interdigitated structure formed by two interleaved combs, whereas the thermistor 17 is formed by two strips of semiconductor material connected to each other at the opposite end to that which terminates with the soldering surfaces 18.

In practice, these deposits are, for example, carried out by the implementation of a microelectronics method comprising in particular the following steps:

depositing polysilicon on the substrate 13 of quartz glass;

forming the pattern of the temperature sensor 17 in the layer of polysilicon, preferably after P-type doping and activation;

depositing electrically insulating material, here silicon nitride Si₃N₄, on at least a portion of the polysilicon pattern;

depositing titanium oxide;

forming the patterns of the conductivity measurement electrodes 15, 16 in the titanium;

depositing titanium oxide as a photo-catalyst;

metallization or on chromium (Cr/Au) and forming the connection areas 18.

In practice, LPCVD (Low Pressure Chemical Vapor Deposition) methods may be used, in particular for the deposit of Si₃N₄ and polysilicon. The patterns are formed by dry attack or attack in a liquid medium.

One of the favored applications of such a conductivity measuring device is its use for the measurement of the Total Organic Carbon (TOC) in a sample of liquid.

For this, the device described with the aide of FIGS. 1 to 3 is completed, as can be seen in FIG. 4, with an ultraviolet (UV) lamp 35, here by virtue of a light-emitting diode, mounted on the upper surface of the upper part 10 of the casing so as to be able to irradiate the conductivity measurement chamber 14 through the opening 31 formed in that upper part.

Moreover, the cavity 32 formed in the lower part 11 is advantageously exploited for the installation of an optical sensor 36 making it possible to detect the signal of the UV lamp 35 for the purpose of quantifying and adjusting the real quantity of energy passing through the sample of ultrapure liquid present in the measurement chamber 14.

Advantageously too, the part of the rear face of the substrate overhanging that cavity may be utilized for the installation of other electronic components related to the TOC measuring device, as indicated above.

The devices for measuring conductivity of an ultrapure liquid and the TOC measurement/verification devices implementing them have, by virtue of the present invention, the following advantages:

1. complete and miniaturized TOC measurement device that is capable of being connected to an item of equipment as a complete sub-assembly

2. elimination of manual assembly on manufacture of these devices

3. effective photo-oxidation

4. increased life of the ultraviolet generating devices

5. UV light emitting diode not requiring any pre-heating

6. sample to analyze not undergoing any pre-heating

7. maximum and instantaneous effectiveness of the UV light-emitting diode

8. possibility of adding a stage for control of the UV

9. better control and adjustment of the emission of the UV by electronics

10. high reproducibility of the UV emission from one TOC measuring device to another

11. possibility of detecting air bubbles, particles, etc. within the conductivity measurement cell

12. reduction of the noise linked to electrical interference, which makes it possible to measure the conductivity at the same time as the photo-oxidation process occurs, and, therefore, possibility of controlling the photo-oxidation process until its completion

13. high reproducibility of the cell constant, and, therefore, necessity to calibrate only a small percentage of a given batch of cells

14. high reproducibility of the temperature sensors in a given batch.

15. obtainment of better temperature detection precision during the conductivity measurements

16. reduction in the manufacturing costs

17. reduction in the photo-oxidation time due to the fact that it is possible to implement a smaller sample volume than those of the state of the art

18. direct measurement due to that small sample volume to measure

19. flexibility in the design of the cells

20. flexibility of incorporation of the conductivity measurement cell in a given device (system for water purification, reservoir, etc.) while respecting the detection limit provided (values in ppt in practice for TOC measuring devices)

21. single use of the conductivity cell may be envisaged

22. elimination of organic contaminants in the absence of the use of adhesive

23. possibility of miniaturizing the TOC measuring device with the possibility of integrating therein various additional electronic components and devices for measurement or detection

24. possibility of obtaining a low cell constant suitable for measuring the conductivity of an ultrapure liquid while reducing the volume of the conductivity measurement chamber to a minimum

It is also to be noted that the xenon UV flash lamp, advantageously coupled to the optical sensor, makes it possible to dissipate the photo-thermal heat supplied by the lamp between the flashes. This has the advantage of not heating the sample. Chemical interference is thus limited. It is known in this connection that in the presence of silica heating of the sample of ultra pure water will lead to disturbance of the conductivity (in particular a reduction).

This absence of heating also limits the contribution of error and uncertainty linked to a high compensation for temperature by an algorithm.

According to one operating mode, the TOC measuring device is implemented with continuous recording of the conductivity, which makes it possible to view the end of the oxidation and to have a dynamic response from oxidation.

In terms of performance, this TOC measuring device makes it possible to take conductivity measurements in real time (in practice, 1 point/s) by accessing the characteristic conductivity profiles of the organic compounds, with possibilities for organic detection at the scale of the ppb, or even smaller.

This detection limit of this device to the ppb is, as a matter of fact, in particular enabled by virtue of recording data approximately every second.

Recording by the second is advantageously enabled by the use of a xenon UV flash lamp, since, between two flashes, a measurement may be coupled and thus no photonic interference perturbs the measurement. No filtering is thus necessary to obtain access to a precise measurement of the temperature and of the conductivity.

The fact of performing a measurement every second also makes it possible to limit chemical interferences due to possible dissolving of CO₂ in the sample of water, due, for example, to defective fluid-tightness.

By virtue of these recorded conductivity profiles, this device may furthermore be adapted to differentiate the behavior of ions, for example from carbon dioxide (CO₂), and of contaminants, for example dichloromethane (CH₂ Cl₂).

More generally, the present invention is not limited to the embodiments described or represented, but covers any variant form.

Other electrode patters may in particular be envisaged, such as two straight parallel electrodes or two interleaved electrodes, one C-shaped and the other straight.

1. A method of manufacturing a device for measuring conductivity of a liquid, said device comprising two conductivity measurement electrodes suitable for defining a cell constant enabling the measurement of the conductivity of said liquid, said method comprising producing each of the electrodes by forming an electrode pattern from electrically conductive material on a substrate of insulating material.

2. A method according to claim 1, wherein said electrode patterns are formed by etching a layer of material deposited beforehand on said substrate or on an underlying layer itself deposited on said substrate.

3. A method according to claim 1, wherein said insulating material of the substrate is selected from the group consisting of quartz glass, polyester and silicon.

4. A method according to claim 1, wherein said electrically conductive material is selected from the group consisting of carbon, platinum, silver, gold, titanium and boron-doped diamond.

5. A method according to claim 1, wherein said electrode patterns take the form of two interleaved combs forming an interdigitated structure.

6. A method according to claim 1, said method further comprising producing a thermistor on said substrate by forming a pattern thereon with conductor or semiconductor material.

7. A method according to claim 6, wherein the material of said thermistor is selected from the group consisting of polysilicon, platinum and boron-doped diamond.

8. A method according to claim 6 or 7, wherein said electrode-forming pattern, when produced on the underlying layer of thermistor-forming material, is separated therefrom by a deposit of electrically insulating material.

9. A device for measuring conductivity of a liquid, said device comprising two conductivity measurement electrodes (15, 16) suitable for defining a cell constant enabling the measurement of the conductivity of said liquid, wherein each electrode takes the form of a pattern of electrically conductive material on a substrate (13) of electrically insulating material.

10. A device according to claim 9, further comprising a cell having a conductivity measurement chamber (14) communicating with the outside of the cell by a liquid inlet and outlet (21, 22) provided in the cell, and at least partially covering the patterns of said conductivity measurement electrodes.

11. A device according to claim 10, wherein said cell comprises two complementary members (12, 13), one comprising a recess forming said conductivity measurement chamber (14) and the other forming the substrate (13), said liquid inlet and outlet of the cell being formed in the substrate-forming member (13).

12. A device according to claim 10, further comprising a casing in two parts (10, 11) by virtue of which said cell is housed and means for assembly by clamping (29a-29d) the two parts suitable for ensuring the fluid-tightness of the conductivity measurement cell.

13. A device according to claim 9, wherein said electrically insulating material of the substrate is selected from the group consisting of quartz glass, polyester and silicon.

14. A device according to claim 9, wherein said electrically conductive material is selected from the group consisting of carbon, platinum, silver, gold, titanium and boron-doped diamond.

15. A device according to claim 9, wherein said electrode patterns take the form of two interleaved combs forming an interdigitated structure.

16. A device according to claim 9, further comprising a thermistor (17) on the substrate.

17. A device according to claim 16, wherein the material of said thermistor is selected from the group consisting of polysilicon, platinum and boron-doped diamond.

18. A device according to claim 16 or 17, wherein said electrode-forming pattern, when produced on the underlying layer of thermistor-forming material, is separated therefrom by a deposit of electrically insulating material.

19. A device according to claim 9, further comprising electronic components specific to the device, on the rear face of said substrate.

20. A device for measuring the Total Organic Carbon content of a sample of liquid comprising:
a device for measuring conductivity comprising two conductivity measurement electrodes suitable for defining a cell constant enabling the measurement of the conductivity of said liquid, wherein each electrode takes the form of a pattern of electrically conductive material on a substrate of electrically insulating material, and a cell having a conductivity measurement chamber communicating with the outside of the cell by a liquid inlet and outlet provided in the cell, and at least partially covering the patterns of said conductivity measurement electrodes, wherein said device has at least one window (12) transparent to ultraviolet rays to perform photo-oxidation of the sample of liquid located in said measurement chamber (14).

21. A device according to claim 20, further comprising, for the photo-oxidation, a UV lamp emitting a wavelength greater than or equal to 360 nm and less than or equal to 400 nm, and a photo-catalyst deposit based on semiconductor material with a wide energy band on said substrate.

22. A device according to claim 20, further comprising, for the photo-oxidation, a xenon flash lamp emitting ultraviolet rays of a wavelength greater than or equal to 160 nm and less than or equal to 400 nm.

23. A device according to claim 21, wherein said wide energy band semiconductor material comprises at least one of a single oxide of a transition metal, a mixed oxide of a transition metal and of an alkali or alkaline-earth metal and of a transition metal sulfide.

24. A device according to claim 23, wherein said semiconductor material is selected from the group consisting of TiO₂, ZnO, Fe₂O₃, ZrO₂, Ta₂O₅, SrTiO₃, CaTiO₃, KTaO₃, CdS and ZnS.

25. A device according to one of claims 21, further comprising an optical sensor (36) arranged at the rear face of said substrate to detect the ultraviolet rays emitted by said ultraviolet lamp.

26. A device according to claim 21, wherein said ultraviolet lamp comprises a light-emitting diode.
